(19) United States
(12) Patent Application Publication
(10) Pub. No.: US 2025/0314915 A1
(43) Pub. Date: Oct. 9, 2025

(54) PROGRAMMABLE PHOTONIC WAVEGUIDES

(71) Applicants: NTT Research, Inc., Sunnyvale, CA (US); CENTER FOR TECHNOLOGY LICENSING, CORNELL UNIVERSITY, Ithaca, NY (US)

(72) Inventors: Tatsuhiro Onodera, Sunnyvale, CA (US); Logan Wright, Sunnyvale, CA (US); Peter McMahon, Sunnyvale, CA (US); Maxim Shcherbakov, Sunnyvale, CA (US); Martin Stein, Sunnyvale, CA (US)

(21) Appl. No.: 18/865,192

(22) PCT Filed: May 12, 2023
(86) PCT No.: PCT/US2023/022090

§ 371 Date: Nov. 12, 2024

Related U.S. Application Data
(60) Provisional application No. 63/341,658, filed on May 13, 2022.

(51) Int. Cl. G02F 1/01

(52) U.S. Cl. CPC G02F 1/0121; G02F 2202/12

(57) ABSTRACT

Methods, devices, and systems for managing programmable photonic waveguides are provided. In one aspect, a method includes: varying respective localized electric fields across a plurality of regions of a waveguide core of a waveguide structure of a programmable photonic waveguide to cause corresponding local variations in at least one of a refractive index or a nonlinear susceptibility of the waveguide core, and programming an optical signal by coupling the optical signal through the waveguide core with the corresponding local variations in the at least one of the refractive index or the nonlinear susceptibility of the waveguide core.

### TECHNICAL FIELD

This disclosure relates generally to integrated photonics, particularly to programmable photonic waveguides.

### BACKGROUND

Integrated photonics, the field of manipulating light in a miniaturized on-chip setting, has the potential to miniaturize a device size, significantly lower energy cost, and increase a device speed for computing and communication applications. However, the potential has been technically difficult to realize due to relatively large process variations in the fabrication process, which can lead to a large degradation in device performance. This issue has been further compounded by a large turn-around time for the fabrication process, frequently leading to a prohibitively expensive and time-consuming R & D cycle.

### SUMMARY

The present disclosure describes methods, apparatus, and systems for implementing programmable photonic waveguides.

One aspect of the present disclosure features a programmable system, including: a programmable device extending in a plane, the programmable device including: a pair of planar electrode layers extending parallel to each other; and a waveguide structure including a core layer and a pair of cladding layers on opposing sides of the core layer, the core layer being between the planar electrode layers, the waveguide structure including a photoconductive material; a power source electrically connected to the planar electrode layers and configured to apply a voltage across the waveguide structure during operation of the programmable system; a light source configured to produce an illumination at a wavelength sufficient to change a conductivity of the photoconductive material; a spatial light controller arranged to receive the illumination from the light source and illuminate the photoconductive material with a patterned illumination sufficient to locally vary the conductivity of the photoconductive material while the voltage is applied across the waveguide structure; and an optical signal source arranged to direct an optical signal to an edge of the waveguide structure to couple the optical signal into the core layer while the photoconductive material is illuminated with the patterned illumination and the voltage is applied across the waveguide structure.

In some embodiments, the patterned illumination is configured to locally vary the conductivity of the photoconductive material sufficient to cause a corresponding local variation in at least one of a refractive index or a nonlinear susceptibility of the core layer during the operation of the programmable system.

In some embodiments, the patterned illumination on the photoconductive material and the voltage applied across the waveguide structure generate local variations of electric fields across a plurality of regions of the core layer so as to cause the corresponding local variations in the at least one of the refractive index or the nonlinear susceptibility of the core layer.

In some embodiments, the corresponding local variation of the refractive index of the core layer is in a range from 10⁻⁴ to more than 0.1.

In some embodiments, the corresponding local variation of a second order nonlinear susceptibility of the core layer is in a range from 1 pm/V to more than 10³ pm/V.

In some embodiments, the core layer includes the photoconductive material.

In some embodiments, at least one of the planar electrode layers is configured as at least part of the cladding layers.

In some embodiments, the core layer is immediately adjacent to the pair of planar electrode layers that are between the pair of cladding layers.

In some embodiments, the photoconductive material is arranged in a layer different from the core layer.

In some embodiments, the layer including the photoconductive material is above the core layer and between an upper planar electrode layer of the planar electrode layers and an upper cladding layer of the cladding layers.

In some embodiments, the spatial light controller includes an optical deflecting device configured to individually deflect respective illumination spots of the illumination onto a plurality of different corresponding areas of a top surface of the programmable device to generate the patterned illumination.

In some embodiments, the optical deflecting device includes a digital micromirror device (DMD).

In some embodiments, the spatial light controller includes an optical scanner configured to sequentially scan an illumination spot of the illumination from the light source across a plurality of different corresponding areas of a top surface of the programmable device to generate the patterned illumination.

In some embodiments, the optical scanner includes a raster optical scanning device.

In some embodiments, the spatial light controller includes a spatial light modulator (SLM) having a plurality of elements configured to be modulated to diffract the illumination from the light source to generate the patterned illumination onto a plurality of different corresponding areas of a top surface of the programmable device.

In some embodiments, the spatial light controller includes a transmissive SLM between the light source and the programmable device.

In some embodiments, the programmable system further includes: a controller coupled to at least one of the power source, the light source, the spatial light controller, or the optical signal source.

In some embodiments, the controller is configured to: generate at least one control signal based on at least one target optical signal, the at least one control signal corresponding to at least one of a two-dimensional (2D) refractive index profile or a 2D nonlinear susceptibility profile in the core layer, and transmit the at least one control signal to the at least one of the power source, the light source, the spatial light controller, or the optical signal source.

In some embodiments, the at least one control signal includes at least one of: a first control signal to the light source to generate a corresponding illumination, a second control signal to the spatial light controller to control the corresponding illumination to generate a corresponding patterned illumination on the photoconductive material, a third control signal to the power source to generate a corresponding voltage to be applied across the waveguide structure, or a fourth control signal to the optical signal source to generate a corresponding input optical signal.

In some embodiments, the programmable system further includes an optical receiver configured to receive an output optical signal coupled out from the waveguide structure.

In some embodiments, the photoconductive material includes at least one of: silicon-rich silicon nitride (SRN), silicon nitride, amorphous silicon, crystalline silicon, liquid crystals, Barium titanate, silicon carbide, aluminum nitride, or lithium niobate.

Another aspect of the present disclosure features a programmable device, including: a waveguide structure extending in a plane and having a core layer and a pair of cladding layers on opposing sides of the core layer; a pair of planar electrode layers extending parallel to each other, the core layer being between the planar electrode layer; and a photoconductive layer including a photoconductive material. In operation of the programmable device, a voltage is applied across the waveguide structure through the planar electrode layers, a patterned illumination of light is projected on individual areas of the photoconductive layer to locally vary a conductivity of the photoconductive material in the photoconductive layer so as to cause corresponding local variations in at least one of a refractive index or a nonlinear susceptibility of the core layer while the voltage is applied across the waveguide structure, and an optical signal is coupled into the core layer and propagates through the core layer with the corresponding local variations in the at least one of the refractive index or the nonlinear susceptibility.

In some embodiments, the core layer includes the photoconductive layer.

In some embodiments, at least one of the planar electrode layers is configured as at least part of the cladding layers.

In some embodiments, the core layer is immediately adjacent to the pair of planar electrode layers that are between the pair of cladding layers.

In some embodiments, the photoconductive layer is different from the core layer.

In some embodiments, the photoconductive layer is above the core layer and between an upper planar electrode layer of the planar electrode layers and an upper cladding layer of the cladding layers.

In some embodiments, the patterned illumination on the photoconductive layer and the voltage applied across the waveguide structure generate local variations of electric fields across a plurality of different corresponding regions of the core layer, so as to cause the corresponding local variations in the at least one of the refractive index or the nonlinear susceptibility of the core layer.

In some embodiments, the photoconductive material includes at least one of: silicon-rich nitride (SRN), silicon nitride, amorphous silicon, crystalline silicon, liquid crystals, Barium titanate, silicon carbide, aluminum nitride, or lithium niobate.

Another aspect of the present disclosure features a programmable device, including: a waveguide structure having a core layer and a pair of cladding layers on opposing sides of the core layer; first and second planar electrode layers extending parallel to each other, the waveguide structure being between the first and second planar electrode layers. The first planar electrode layer includes a plurality of pixelated electrodes insulated from each other, each of the pixelated electrodes being individually controlled to receive a respective voltage, and the second planar electrode layer is commonly coupled to a ground. In operation of the programmable device, individual voltages are applied to the plurality of pixelated electrodes to generate locally varying electric fields across the core layer so as to cause corresponding local variations in at least one of a refractive index or a nonlinear susceptibility of the core layer, and an optical signal is coupled into the core layer and propagates within the core layer with the corresponding local variations in the at least one of the refractive index or the nonlinear susceptibility.

Another aspect of the present disclosure features a programmable device, including: a one-dimensional waveguide structure extending along a longitudinal direction and having a waveguide core, and a cladding layer surrounding the waveguide core; a photoconductive layer including a photoconductive material and extending along the longitudinal direction, first and second planar electrode layers extending parallel to each other along the longitudinal direction, the waveguide structure being between the first and second planar electrode layers. In operation of the programmable device, a voltage is applied across the waveguide structure through the planar electrode layers, a patterned illumination of light is projected on a plurality of different corresponding areas of the photoconductive layer along the longitudinal direction to locally vary a conductivity of the photoconductive material in the photoconductive layer so as to cause corresponding local variations in at least one of a refractive index or a nonlinear susceptibility of the waveguide core along the longitudinal direction while the voltage is applied across the waveguide structure, and an optical signal is coupled into the waveguide core and propagates through the waveguide core with the corresponding local variations in the at least one of the refractive index or the nonlinear susceptibility along the longitudinal direction.

Another aspect of the present disclosure features a method of managing a programmable device, including: illuminating light on the programmable device to produce a patterned illumination of the light on a photoconductive layer of the programmable device, so as to locally vary a conductivity of a photoconductive material in the photoconductive layer, where the programmable device extends in a plane and includes a waveguide structure having a core layer and a pair of cladding layers on opposing sides of the core layer; while illuminating the light on the programmable device, applying a voltage across the waveguide structure through a pair of planar electrode layers of the programmable device so as to cause corresponding local variations in at least one of a refractive index or a nonlinear susceptibility of the core layer; and programming an optical signal by coupling the optical signal through the core layer with the corresponding local variations in the at least one of the refractive index or the nonlinear susceptibility of the core layer.

In some embodiments, the core layer includes the photoconductive layer.

In some embodiments, the photoconductive layer is arranged between an upper planar electrode layer of the planar electrode layers and an upper cladding layer of the cladding layers, and the light is illuminated on the photoconductive layer through the upper planar electrode layer.

In some embodiments, illuminating the light on the programmable device includes: individually deflecting respective illumination spots of the light onto a plurality of different corresponding areas of a top surface of the programmable device to produce the patterned illumination of the light.

In some embodiments, illuminating the light on the programmable device includes: sequentially scanning an illumination spot of the light across a plurality of different corresponding areas of a top surface of the programmable device to generate the patterned illumination.

In some embodiments, illuminating the light on the programmable device includes: modulating a plurality of elements of a spatial light modulator (SLM) to diffract the light to generate the patterned illumination onto a plurality of different corresponding areas of a top surface of the programmable device.

In some embodiments, the method further includes: generating at least one control signal based on at least one target optical signal, the at least one control signal corresponding to at least one of a two-dimensional (2D) refractive index profile or a 2D nonlinear susceptibility profile in the core layer; and using the control signal to control at least one of: the illumination of the light on the programmable device, the voltage applied across the waveguide structure, or the optical signal coupled through the core layer.

In some embodiments, the method further includes: receiving the programmed optical signal coupled out from the core layer; and adjusting the control signal based on a result of comparing the programmed optical signal to the at least one target optical signal.

Another aspect of the present disclosure features a method of managing a programmable device, including: varying respective localized electric fields across a plurality of regions of a waveguide core of a waveguide structure in the programmable device to cause corresponding local variations in at least one of a refractive index or a nonlinear susceptibility of the waveguide core; and programming an optical signal by coupling the optical signal through the waveguide core with the corresponding local variations in the at least one of the refractive index or the nonlinear susceptibility of the waveguide core.

In some embodiments, varying the respective localized electric fields across the plurality of regions of the waveguide core includes: illuminating light on the waveguide structure of the programmable device to produce a patterned illumination of the light on a photoconductive material in the waveguide structure, so as to locally vary a conductivity of the photoconductive material; and while illuminating the light on the waveguide structure, applying a voltage across the waveguide structure to cause the varying of the respective localized electric fields across the plurality of regions of the waveguide core, the patterned illumination of the light on the photoconductive material corresponding to the plurality of regions of the waveguide core.

In some embodiments, the waveguide structure is between first and second planar electrode layers, the first planar electrode layer includes a plurality of pixelated electrodes configured to receive respective voltages, and the second planar electrode layer is commonly coupled to a ground. In some embodiments, varying the respective localized electric fields across the plurality of regions of the waveguide core includes: changing the respective voltages coupled to the plurality of pixelated electrodes to vary the respective localized electric fields across the plurality of regions of the waveguide core, the plurality of pixelated electrodes corresponding to the plurality of regions of the waveguide core.

In some embodiments, the waveguide structure includes one of a one-dimensional (1D) waveguide extending along a longitudinal direction, or a two-dimensional (2D) waveguide extending in a plane.

Another aspect of the present disclosure features a method of fabricating a programmable system as described herein.

Another aspect of the present disclosure features a method of fabricating a programmable device as described herein.

The implementations described herein can provide various technical benefits and advantages. First, the techniques can address the fabrication process issues for conventional integrated photonic devices. Here, a programmable photonic waveguide can be fabricated once and the functionality of the photonic waveguide can be programmed post hoc, which is analogous to how an integrated electronic circuit is able to take on different or even new functionalities via uploading software programs. Accordingly, the techniques can reduce or eliminate large process variations, shorten fabrication time, and improve fabrication yield and device performance. Second, the programmable photonic waveguide is made of multiple stacked layers, which can easily fabricated with conventional deposition technologies (e.g., Metal-Organic Chemical Vapor Deposition (MOCVD) or molecular beam epitaxy (MBE)), without fabricating complicated microstructures or nanostructures in the waveguide (e.g., using nanolithography). Thus, it can be less time and labor consuming, more reliable and more repeatable. Third, any desired number of regions in a waveguide core of the photonic waveguide can be virtually formed or changed, e.g., by producing different patterned illuminations on a photoconductive layer corresponding to the waveguide core, without actual fabrication. Fourth, the programmable photonic waveguide can be reprogrammed for an arbitrary number of times (e.g., up to wear and tear like in electronic circuits). In contrast, devices using phase change materials have a finite number (e.g., thousands) of rewrites before the phase change materials are permanently damaged. Fifth, the techniques can significantly increase the degree of control over light in the programmable photonic waveguide, e.g., the number of parameters in the photonic waveguide, compared to other approaches, e.g., using a phase change material or elementary unit cells of optical phase shifters. Sixth, the techniques enable to change a refractive index and a nonlinear susceptibility of a photonic waveguide, which are fundamental physical properties of any given optical medium that dictates how light travels in the photonic waveguide. Thus, the techniques can integrate a number of optical devices in a single chip to implement a number of corresponding optical functions, which can miniaturize a size of a photonic system and increase its functionality. Seventh, the techniques can be applied to any suitable devices, e.g., one-dimensional (1D) devices, two-dimensional (2D) devices, or three-dimensional (3D) devices, any suitable systems, or any suitable applications, e.g., machine learning, optical computing, and telecommunication.

The details of one or more disclosed implementations are set forth in the accompanying drawings and the description below. Other features, aspects, and advantages will become apparent from the description, the drawings and the claims.

### BRIEF DESCRIPTION OF THE DRAWINGS

FIG. 1 is a schematic diagram showing a principle of an example programmable photonic planar waveguide.

FIG. 2 is a schematic diagram of an example system including an example programmable photonic planar waveguide having a photoconductive core.

FIG. 3 is a schematic diagram of another example system including an example programmable photonic planar waveguide.

FIG. 4A is a schematic diagram of an example system including another example programmable photonic planar waveguide having a photoconductive layer different from a core layer.

FIG. 4B shows equivalent circuit diagrams of the programmable photonic planar waveguide of FIG. 4A in light on and light off scenarios.

FIG. 5 is a schematic diagram of another example system including an example programmable photonic planar waveguide.

FIG. 6A is a flowchart of an example process of managing a programmable photonic waveguide.

FIG. 6B is a flowchart of an example process of generating localized electric fields in a waveguide core.

Like reference numbers and designations in the various drawings indicate like elements. It is also to be understood that the various exemplary implementations shown in the figures are merely illustrative representations and are not necessarily drawn to scale.

### DETAILED DESCRIPTION

Implementations of the present disclosure provide methods, devices, systems and techniques for managing programmable photonic waveguides to control wave dynamics of light that travels in the photonic waveguides.

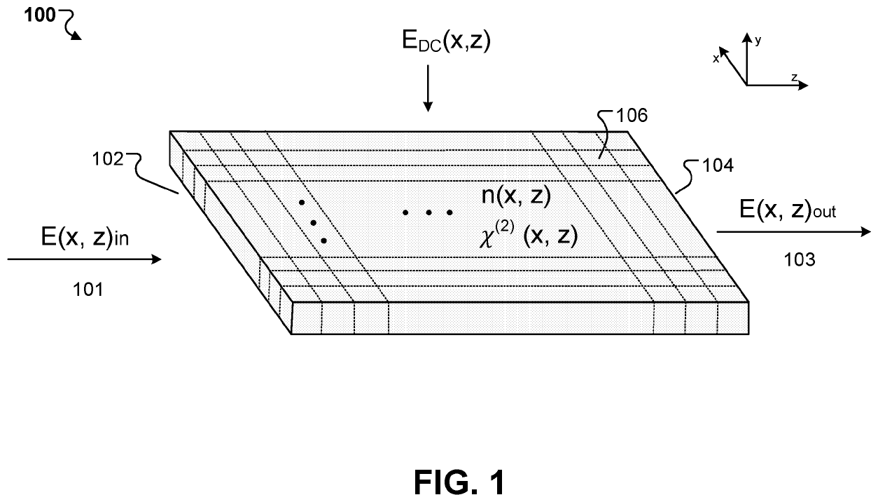

For example, as described with further details in FIG. 1, a programmable photonic waveguide can be controlled (or programmed) by varying respective localized electric fields across a waveguide core of the photonic waveguide to cause corresponding local variations in at least one of a refractive index or a nonlinear susceptibility of the waveguide core. When an optical signal (e.g., a laser pulse) is coupled into the waveguide core with the corresponding local variations of in the at least one of the refractive index or the nonlinear susceptibility, the optical signal can be programmed into a target optical signal at an output of the waveguide core. Thus, the photonic waveguide can be programmed to obtain the target optical signal, without changing the physical structure of the photonic waveguide.

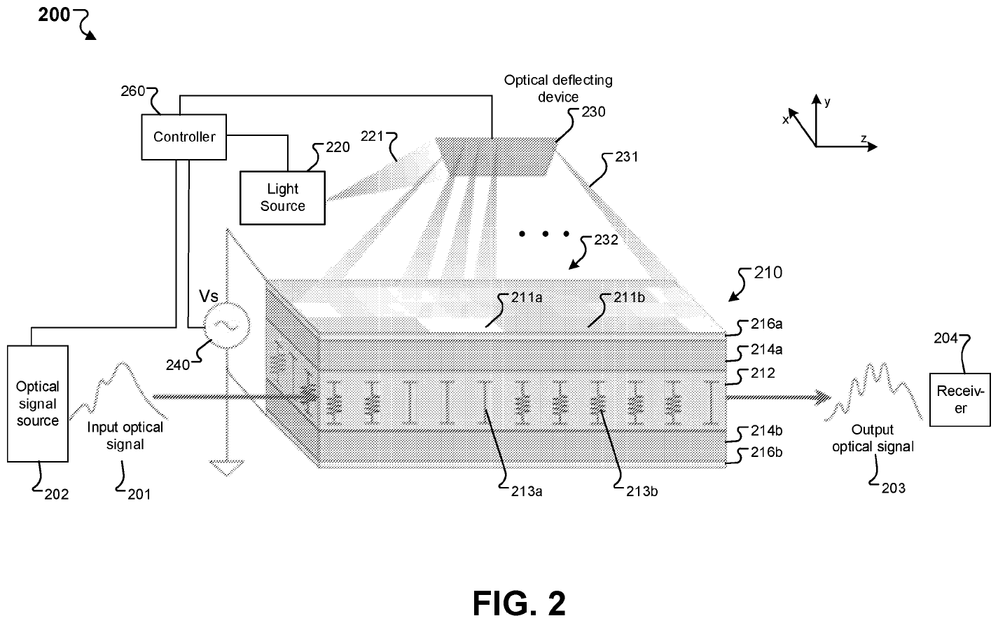

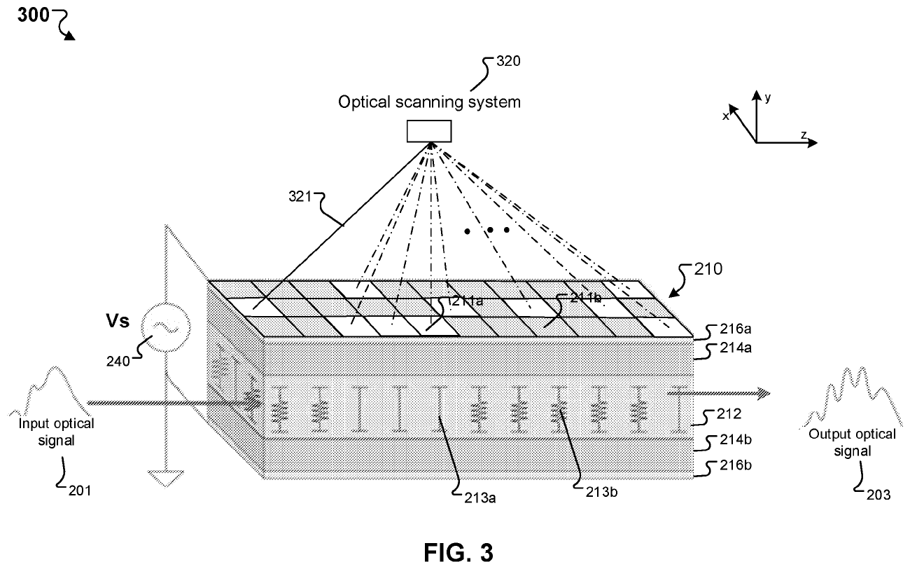

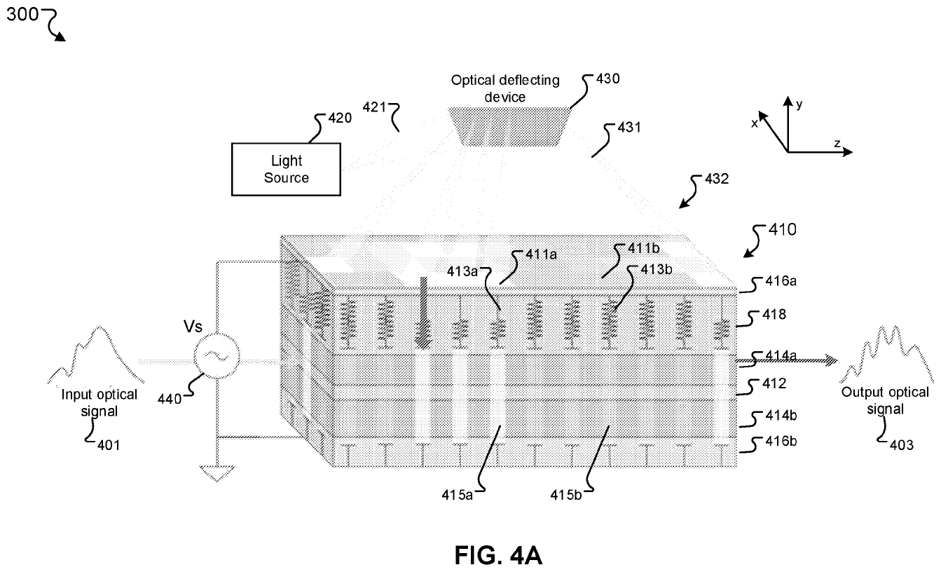

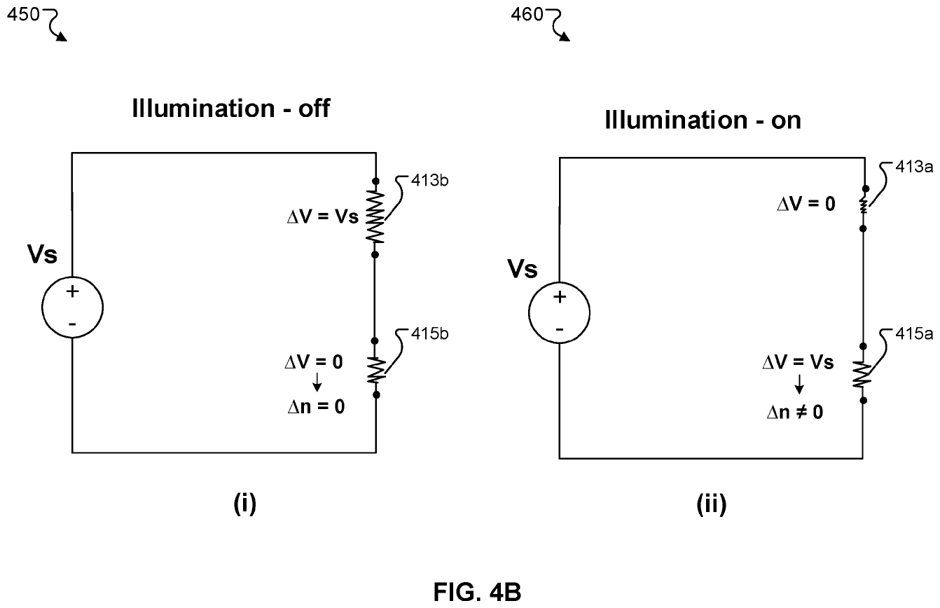

In some implementations, as described with further details in FIGS. 2, 3, and 4A-4B, a programmable photonic waveguide can include a photoconductive layer in a waveguide structure. The photoconductive layer can be in a waveguide core as described in FIG. 2 or 3, or in a layer between an electrode layer and a cladding layer as described in FIGS. 4A-4B. A spatial light controller can be configured to direct a patterned illumination on a plurality of different corresponding areas of the photoconductive layer to locally vary the conductivity of a photoconductive material (or photoresistors) in the photoconductive layer. In some examples, the patterned illumination refers to a light pattern having illumination on selected areas of a surface (or a layer) and no illumination on the other areas of the surface (or the layer). In some examples, the patterned illumination refers to a light pattern having light intensity higher than a threshold intensity on selected areas of the surface (or the layer) and having light intensity lower than the threshold intensity on the other areas of the surface (or the layer). In some examples, the patterned illumination refers to a polarization variation or a spectral variation on different areas across the surface (or the layer).

While the pattern illumination is on the plurality of different corresponding areas of the photoconductive layer, a voltage is applied across the photonic waveguide to vary respective localized electric fields across the waveguide core of the photonic waveguide to thereby cause the corresponding local variations in at least one of a refractive index or a nonlinear susceptibility of the waveguide core, e.g., due to direct current (DC) Kerr effect or electric field induced second harmonic (EFISH) effect. The spatial light controller can include an optical deflecting device such as DMD as described in FIG. 2, an optical scanner such as a raster optical scanning device as described in FIG. 3, or a spatial light modulator (SLM).

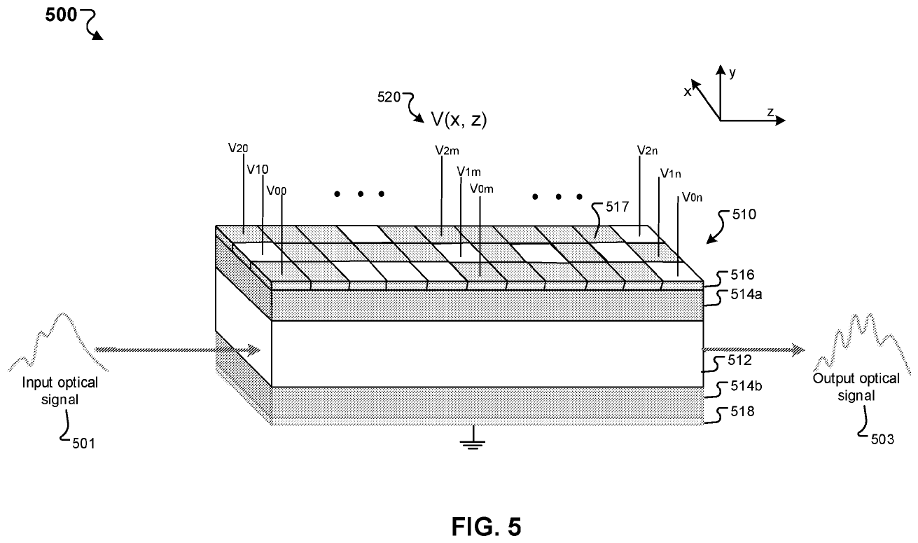

In some implementations, as described with further details in FIG. 5, a programmable photonic waveguide can include a pixelated electrode layer on top of a waveguide structure having a waveguide core between cladding layers. Each pixelated electrode in the pixelated electrode layer can be configured to receive a respective voltage. The respective voltages to the pixelated electrodes can be controlled to vary respective localized electric fields across different regions of the waveguide core to cause corresponding local variations in at least one of a refractive index or a nonlinear susceptibility of the waveguide core.

### Principle

FIG. 1 illustrates a working principle of an example programmable photonic waveguide 100. As an example, the photonic waveguide 100 is described as a 2D planar waveguide extending in a plane, e.g., XZ plane. Light that travels in the photonic waveguide 100 is confined in a vertical dimension perpendicular to the plane, e.g., Y dimension.

The photonic waveguide 100 can include a waveguide core between a pair of cladding layers. An input optical signal 101, e.g., having an electric field expressed as E(x,z)ᵢₙ, can be coupled into the waveguide core from a first edge 102 of the photonic waveguide 100, travel in the photonic waveguide 100, and be coupled out from a second, opposite edge 104 of the photonic waveguide 100 as an output optical signal 103, e.g., e.g., having an electric field expressed as E(x,z)ₒᵤₜ. A property of the output optical signal 103 is determined based on a property of the input optical signal 101 and a property of the photonic waveguide 100.

A voltage can be applied across the photonic waveguide 100, e.g., through a pair of planar electrode layers, to generate a direct current (DC) electric field E_{DC} across the waveguide core, e.g., along Y dimension. Based on electro-optic modulation, the electric field can subsequently induce a change of a refractive index and/or a nonlinear susceptibility of a material of the waveguide core of the photonic waveguide 100.

Refractive index n₀ of the material of the waveguide core can have a linear change. According to DC-Kerr effect, in one example, the linear change of the refractive index Δn can be expressed as:

$$Δ n = 6 {χ}^{( 3 )} {E}_{DC}^{2} / {n}_{0} , \qquad ( 1 )$$

where χ⁽³⁾ is nonlinear third order susceptibility of the material of the waveguide core, and E_{DC} is the electric field applied across the waveguide core.

The refractive index n₀ of the material of the waveguide core can also experience a nonlinear change. According to electric field-induced second harmonic (EFISH) effect, in one example, nonlinear second order susceptibility χ⁽²⁾ can be expressed as:

$${χ}^{( 2 )} = 3 {χ}^{( 3 )} {E}_{DC} . \qquad ( 2 )$$

Thus, by configuring the material of the waveguide core (e.g., χ⁽³⁾) and the electric field E_{DC} across the waveguide core, the change of the refractive index Δn and/or the nonlinear second order susceptibility χ⁽²⁾ can be controlled. For example, if the material of the waveguide core has a greater nonlinear third order susceptibility χ⁽³⁾ and/or a greater break down electric field E_{Breakdown}, the change of the refractive index Δn and/or the nonlinear second order susceptibility χ⁽²⁾ can be greater. Additionally, the change of the refractive index Δn and the nonlinear second order susceptibility χ⁽²⁾ can vary together with each other.

In one example, silicon has χ⁽³⁾ of 2.5×10⁻¹⁹ m²V⁻² and E_{Breakdown} of 40 V/μm. Accordingly, silicon can have a maximum refractive index change Δn of 2×10⁻⁴, and a maximum nonlinear second order susceptibility χ⁽²⁾ of 40 pm/V. In another example, silicon-rich silicon nitride (SRN) has χ⁽³⁾ of 2.5×10⁻¹⁹ m²V⁻² and E_{Breakdown} of 400 V/μm to 1200 V/μm. Accordingly, SRN can have a maximum refractive index change Δn in a range from 0.02 to 0.2, which can be two or three orders of magnitude larger than that of silicon. SRN can also have a maximum nonlinear second order susceptibility χ⁽²⁾ in a range from 400 pm/V to 1200 pm/V, which can be one or two orders of magnitude larger than that of silicon.

As refractive index and nonlinear susceptibility are fundamental physical properties of any given optical media, a programmable photonic device such as a photonic waveguide can be achieved by using a suitable material (e.g., SRN) for a waveguide core and controlled by a suitable electric field across the waveguide core.

If localized electric fields E_{DC}(x,z) across a plane are applied across a plurality of regions 106 of the waveguide core in the plane, e.g., as illustrated in FIG. 1, each region of the waveguide core can be applied with a respective localized electric field E_{DC}(x,z) to cause a corresponding local variation in at least one of a refractive index or a nonlinear susceptibility. In such a way, an optical signal travelling through the waveguide core can be locally programmed or manipulated into a target signal with desirable properties or characteristics.

In some implementations, as described with further details in FIG. 5, a pixelated electrode layer including an array of pixelated electrodes can be formed on top of the photonic waveguide. The array of pixelated electrodes can be physically fabricated (e.g., by photolithography), which may also define a resolution of the programmable photonic waveguide. Each pixelated electrode in the pixelated electrode layer can be configured to receive a respective voltage V_{DC}(x,z). The respective voltages to the pixelated electrodes can be controlled to vary respective localized electric fields E_{DC}(x,z) across different regions of the waveguide core to cause corresponding local variations in at least one of a refractive index or a nonlinear susceptibility of the waveguide core.

In some implementations, the plurality of regions 106 of the waveguide core can be virtually (and optionally dynamically) defined by a profile of the localized electric fields. The localized electric fields can be obtained by a patterned illumination of light on a photoconductive layer in the photonic waveguide, e.g., as illustrated in FIG. 2, 3, or 4A-4B. A wavelength of the light can be chosen to vary a conductivity of a photoconductive material in the photoconductive layer. The patterned illumination can correspond to different areas of the photoconductive layer which can correspond to the plurality of regions 106 of the waveguide core.

When no illumination is on an area of the photoconductive layer, there is no or little change in the refractive index of the photoconductive material and a photoresistor in the area. In contrast, when an illumination spot is on an area of the photoconductive layer, the conductivity of the photoconductive material in the area can become larger, and accordingly a refractive index of the photoconductive material in the area can become smaller and a photoresistor of the area can become smaller. While the pattern illumination is on the different areas of the photoconductive layer to cause localized variations of the refractive index or photoresistors, a voltage can be applied across the photonic waveguide to therefore generate respective localized electric fields across the waveguide core of the photonic waveguide to thereby cause the corresponding local variations in at least one of a refractive index or a nonlinear susceptibility of the waveguide core. Thus, the photoconductive material with a high photoconductivity can increase the corresponding local variations in the at least one of the refractive index or the nonlinear susceptibility of the waveguide core.

In some implementations, the photoconductive material is chosen to have low loss, high breakdown field, high χ⁽³⁾ nonlinearity, and/or high photoconductivity. In some examples, the photoconductive material includes at least one of: silicon-rich silicon nitride (SRN), silicon nitride, silicon carbide, amorphous silicon, crystalline silicon, liquid crystals, Barium titanate, or lithium niobate.

### Example Programmable Waveguide Systems and Devices

FIG. 2 is a schematic diagram of an example system 200 including an example programmable photonic planar waveguide 210.

Similar to the photonic waveguide 100 of FIG. 1, the photonic planar waveguide 210 extends in a plane (e.g., XZ plane). The photonic planar waveguide 210 includes a photonic component and an electronic component. The photonic component includes a core layer (or a waveguide core) 212 and a pair of cladding layers 214a, 214b on opposite sides of the core layer 212, which collectively form a photonic 2D slab waveguide that is able to confine light in a vertical dimension (e.g., Y dimension). A material of the core layer 212 has a higher refractive index than that of a material of the cladding layers 214a, 214b, such that the light can be confined in the core layer 212 by total internal reflection and travels within the core layer 212.

The electrical component includes electrodes formed on extreme ends of the photonic planar waveguide 210, e.g., an upper planar electrode layer 216a and a lower planar electrode layer 216b respectively on an upper cladding layer 214a and a lower cladding layer 214b along the vertical dimension. The planar electrode layers 216a, 216b are electrically coupled to a power source 240, e.g., a voltage source such as a battery or a voltage generator, or a current source. An electric DC voltage V can be applied across the planar electrode layers 216a, 216b to generate a DC electric field across the core layer 212.

As illustrated in FIG. 1, the photonic planar waveguide 210 can be a multi-layer structure having a stack of planar layers including the core layer 212, the cladding layers 214a, 214b, and the planar electrode layers 216a, 216b. The multi-layer structure can be fabricated, e.g., by Metal-Organic Chemical Vapor Deposition (MOCVD), molecular beam epitaxy (MBE), atomic layer deposition (ALD), physical vapor deposition (PVD), Chemical Vapor Deposition (CVD), or any other deposition methods in a vacuum chamber.

The system 200 can include an optical signal source 202 configured to provide an input optical signal 201. For example, the optical signal source 202 can be a pulsed laser source, and the input optical signal 201 can include one or more laser pulses. The input optical signal 201 can be coupled into the core layer 212 through an edge of the photonic planar waveguide 210, propagates through the core layer 212, and coupled out from the core layer 212 into an output optical signal 203. The output optical signal 203 can be received by an optical receiver 204. The input optical signal 201 can be at any desired wavelength, e.g., from 500 nm to 5000 nm. In some examples, the input optical signal 201 can be modulated in space first using a spatial light modulator and/or in time/frequency domain using an electro-optic modulator. In some examples, the input optical signal 201 can include one or more laser pulses each having a duration, e.g., nanosecond (ns), picosecond (ps), or femtosecond (fs). The input optical signal 201 can have a modulation frequency, e.g., ˜100 s MHz. In some examples, the input optical signal includes continuous wave (CW) light. As noted above, a characteristic or property of the output optical signal 203 is determined based on a characteristic or property of the input optical signal 201 and a characteristic or property of the photonic planar waveguide 100. Thus, to perform a desired function or operation on the input optical signal 201 and/or to obtain a desired output optical signal 203, the photonic planar waveguide 210 can be programmed.

In some implementations, as illustrated in FIG. 2, the core layer 212 of the photonic planar waveguide 210 can be made of a photoconductive material, such that the photonic planar waveguide 210 can be programmed (or controlled) by projecting a patterned illumination 232 of light on the core layer 212 to locally change a conductivity of the photoconductive material in the core layer 212 and thereby cause local variations of electric fields across the core layer 212. Based on electro-optic modulation, the local variations of the electric fields can subsequently induce a change in a refractive index (e.g., Δn) and a nonlinear susceptibility (e.g., χ⁽²⁾) of the photonic planar waveguide 210. To achieve the large change in Δn and χ⁽²⁾, the photoconductive material can be chosen to have low loss, high breakdown field, high χ⁽³⁾ nonlinearity, and/or high photoconductivity. In some examples, the photoconductive material includes silicon-rich silicon nitride (SRN), silicon nitride, silicon carbide, aluminum nitride, amorphous silicon, crystalline silicon, liquid crystals, Barium titanate, or lithium niobate.

In some implementations, as illustrated in FIG. 2, the patterned illumination 232 can be achieved by an optical deflecting device 230 receiving an illumination 221 from a light source 220 and individually deflecting respective illumination spots 231 to a plurality of different areas 211a on a top surface of the photonic planar waveguide 210 (e.g., a top surface of the upper planar electrode layer 216a). For example, the optical deflecting device 230 can include a digital micromirror device (DMD) that can have on its surface a number of (e.g., thousands of) microscopic mirrors arranged in a rectangular array. The mirrors can be individually rotated in a range of angles, e.g., ±10°-12°, to an on or off state. In the on state, the illumination spot 231 is deflected (e.g., reflected) onto a corresponding area, e.g., 211a, on the top surface. In the off state, the illumination spot 231 is directed elsewhere, such as no illumination is onto a corresponding area, e.g., 211b.

Layers on top of the core layer 212, e.g., the upper planar electrode layer 216a and the upper cladding layer 214a, can be made of a transparent or a partially-transparent material, such that the illumination spot 231 can be transmitted onto the core layer 212 to change a conductivity of the photoconductive material in a corresponding region in the core layer 212. In some examples, amorphous silicon or silicon-rich silicon nitride (SRN) can be used for the photoconductive material, silicon dioxide can be used for the cladding layer 214a, 214b, and indium tin oxide (ITO) can be used for the planar electrode layer 216a. The planar electrode layer 216b can be made of ITO or a metal such as gold.

The illumination 221 from the light source 220 can have a wavelength sufficient to change a conductivity of the photoconductive material. The wavelength can be chosen based on the photoconductive material, e.g., whether the photoconductive material can absorb light with the wavelength or whether photon energy of light with the wavelength is greater than the bandgap of the photoconductive material. The bandgap of a material can be tuned by synthesizing with one or more other materials. For example, if the photoconductive material is amorphous silicon, the wavelength sufficient to change the conductivity of the amorphous silicon can be in a range, e.g. from 200 nm to 700 nm. If the photoconductive material is silicon-rich Silicon Nitride (SRN), the wavelength sufficient to change the conductivity of the SRN can be in a range, e.g., from 500 nm to 800 nm. In some examples, the light source 220 includes a laser, a laser diode, or a light emitting diode (LED) providing light in a range, e.g., from 100 nm to 2000 nm. For example, the light source 220 can be an ultraviolent (UV) LED producing light with a wavelength in a range from 100 nm to 400 nm, a blue LED producing light with a wavelength in a range from 400 nm to 500 nm, a green LED producing light with a wavelength in a range from 500 nm to 565 nm, or a red LED producing light with a wavelength in a range from 600 nm to 700 nm. As another example, the light source 220 can be a near-infrared laser diode producing light with a wavelength in a range from 705 nm to 2000 nm.

Note that the illumination 221 from the light source can have a different wavelength from that of the input optical signal 201. As noted above, the illumination 221 has a wavelength sufficient to change a conductivity of the photoconductive material, and the wavelength of the illumination 221 is determined based on the property of the photoconductive material. In contrast, a wavelength of the input optical signal 201 is determined based on a target signal to be achieved, and the wavelength of the input optical signal 201 can be sufficient to travel in the core layer 212 of the photonic waveguide 210.

When no illumination is on the photoconductive material of a region, there is no or little change in a refractive index of the photoconductive material and a photoresistor of the region. In contrast, when an illumination spot is on the photoconductive material of a region, the conductivity of the photoconductive material in the region can become larger, and accordingly a refractive index of the photoconductive material in the area can become smaller and a photoresistor of the area can become smaller.

As illustrated in FIG. 2, a first region corresponding to the area 211b with no illumination has a photoresistor 213b, while a second region corresponding to the area 211a with illumination has a photoresistor 213a that can be much smaller to the photoresistor 213b. Thus, the patterned illumination 232 on different regions of the core layer 212 can cause localized variations of the photoresistors in different regions of the core layer 212. When the voltage Vs is applied across the photonic planar waveguide 210 to generate an electric field across the core layer 212, the patterned illumination 232 can be directly translated to a spatial electric field distribution across the different regions of the core layer 212. Leveraging the Kerr effect and the electric field induced second harmonic (EFISH) effect in optics, the programmed electric field across the core layer 212 can induce a change in the refractive index and nonlinear susceptibility of the core layer 212. Through configuring or managing the fundamental optical properties, the photonic planar waveguide 210 can be used to programmatically manipulate the light. For example, as illustrated in FIG. 2, the output optical signal 203 can have a different pulse profile from that of the input optical signal 201.

As the regions in the core layer 212 correspond to different areas 211a, 211b on the top surface of the photonic planar waveguide 210 that are defined by the patterned illumination 232, the regions are virtually generated and can be changed dynamically as desired. A resolution of a region in the core layer 212, e.g., the smallest size of the region, can be determined, not by a manufacturing limit, but by a diffraction limit of the illumination 221 from the light source 220, e.g., according to the Rayleigh criterion. The diffraction limit can be 100 s nm.

As the patterned illumination changes the photoconductivity of the photoconductive material and thus the photoresistor in the region including the photoconductive material and the electric field is applied across the core layer 212, a response time of the photonic planar waveguide 210 can be limited by a time constant of an equivalent RC (resistor-capacitance) circuit, e.g., microsecond (μs).

In some implementations, to shorten the response time and increase an operation frequency of the photonic planar waveguide 210, the planar electrode layers 216a, 216b can be configured as at least part of the cladding layers 214a, 214b. For example, the planar electrode layers 216a, 216b can be between the cladding layers 214a, 214b and arranged immediately on opposite sides of the core layer 212. That is, the core layer 212 can be immediately adjacent to the planar electrode layers 216a, 216b. In such a way, the response time of the photonic planar waveguide 210 can be shorten to, e.g., nanosecond (ns), and the operation frequency can be up to GHz. Moreover, by using the planar electrode layers 216a, 216b to simultaneously serve as at least part of the cladding layers 214a, 214b, the photonic planar waveguide 210 can be miniaturized to a smaller size than the photonic planar waveguide 210 shown in FIG. 2.

In some implementations, the system 200 includes a controller 260 that can be coupled to at least one of the optical signal source 202, the power source 340, the light source 220, the optical deflecting device 230, or the optical receiver 204. The controller 260 can include one or more processing units (e.g., processors) configured to generate at least one control signal based on at least one target optical signal. The at least one control signal can correspond to at least one of a two-dimensional (2D) refractive index profile and/or a 2D nonlinear susceptibility profile in the core layer. The controller 260 can transmit the at least one control signal to the at least one of the optical signal source 202, the light source 220, the optical deflecting device 230, or the power source 240.

In some examples, the at least one control signal includes at least one of: a first control signal to the light source 220 to generate a corresponding illumination 221 (e.g., with a desired wavelength and/or a desired intensity), a second control signal to the optical deflecting device 230 to control the corresponding illumination 221 to generate a corresponding patterned illumination 232 on the photoconductive material, a third control signal to the power source 240 to generate a corresponding voltage (e.g., thousands of volts) to be applied across the photonic planar waveguide 210, or a fourth control signal to the optical signal source 202 to generate a corresponding input optical signal 201 (e.g., with a specific pulse profile).

In some examples, the controller 260 can receive the output optical signal 203, e.g., the programmed optical signal from the photonic planar waveguide 210, from the optical receiver 204, and adjust the control signal based on a result of comparing the output optical signal 203 to the at least one target optical signal used to generate the control signal.

In some implementations, parameters of the system 200, e.g., the patterned illumination 232, can be determined either in software via physical simulation of the system 200, in hardware by rapidly iterating among different possible configurations or designs, or via a combination of those.

FIG. 3 is a schematic diagram of another example system 300 including an example programmable photonic planar waveguide 210. The system 300 is similar to the system 200 of FIG. 2, except that the system 300 sequentially generates a patterned illumination on a plurality of different areas of a top surface of the photonic planar waveguide 210 by an optical scanning system 320, e.g., a raster optical scanning system.

In the system 200, the optical deflecting device 230 of FIG. 2 simultaneously deflects multiple illumination spots, e.g., by tilting angles of a number of mirrors, to a plurality of corresponding areas on the top surface of the photonic planar waveguide 210. In contrast, in the system 300, the optical scanning system 320 repetitively scans an illumination spot 321 (e.g., a focused laser spot) across a plane of the top surface of the photonic planar waveguide 210 to illuminate selected areas 211a to generate the patterned illumination. The optical scanning system 320 can have a high scanning frequency, such that the input optical signal 201 can be continuously manipulated in the core layer 212.

In some implementations, besides the optical deflecting device 230 of FIG. 2 or the optical scanning system 320 of FIG. 3, a spatial light modulator (SLM) can be used to generate the patterned illumination onto different corresponding areas of a top surface of a photonic planar waveguide. The SLM includes a plurality of elements each that can be modulated by respective control signals to diffract an illumination, e.g., from the light source 220 of FIG. 2, toward the different corresponding areas of the top surface. The SLM can be a transmissive SLM arranged between the light source and the photonic planar waveguide.

FIG. 4A is a schematic diagram of an example system 400 including another example programmable photonic planar waveguide 410.

Different from the photonic planar waveguide 210 where the photoconductive material is included in the core layer 212, the photonic planar waveguide 410 can include a non-photoconductive waveguide material (e.g., SiN or Silicon) as a material of a core layer 412 that is between a pair of cladding layers 414a, 414b (e.g., 214a, 214b of FIG. 2 or 3). Instead, the photonic planar waveguide 410 includes a photoconductive layer 418 arranged outside of the core layer 412, e.g., between an upper cladding layer 414a and an upper planar electrode layer 416a (e.g., 216a of FIG. 2 or 3). In this way, more exotic/diversity of materials can be independently and separately chosen for the core layer 412 and the photoconductive layer 418.

Similar to the photonic planar waveguide 210, the photonic planar waveguide 410 includes a pair of planar electrode layers on both ends, including the upper planar electrode layer 416a and a lower planar electrode layer 416b (e.g., 216b of FIG. 2 or 3). The planar electrode layers 416a, 416b are electrically coupled to a power source 440, e.g., 240 of FIG. 2, and receive a voltage Vs to be applied across the photonic planar waveguide 410.

Also, similar to the photonic planar waveguide 210, the photonic planar waveguide 410 is illuminated by a patterned illumination 432 (e.g., 232 of FIG. 2) on a top surface of the photonic planar waveguide 410, e.g., by an optical deflecting device 430 receiving an illumination 421 from a light source 420 (e.g., 220 of FIG. 2) and deflecting multiple illumination spots 431 onto the top surface. Note that other illumination methods as discussed above, e.g., using the optical scanning system 320 of FIG. 3 or using SLM, can be also applied here to generate the patterned illumination 432.

As noted above, the illumination on a photoconductive material can change a conductivity of the photoconductive material and thus a photoresistor of a region including the photoconductive material. For example, a photoresistor of a region corresponding to an area 411b without illumination can be labelled as 413b, and a photoresistor of a region corresponding to an area 411a with illumination can be labelled as 413a. As illustrated in FIG. 4A, the photoresistor 413a can be substantially smaller than the photoresistor 413b, due to the change of the conductivity of the photoconductive material with the illumination.

FIG. 4B shows equivalent circuit diagrams 450, 460 of the programmable photonic planar waveguide 410 of FIG. 4A in illumination off scenario (i) and illumination on scenario (ii). In the equivalent circuit diagram 450, the photoresistor 413b formed in the photoconductive layer 418 and a corresponding resistor 415b formed in a waveguide structure including the core layer 412 and the cladding layers 414a, 414b are coupled in series to the voltage Vs. In the equivalent circuit diagram 460, the photoresistor 413a formed in the photoconductive layer 418 and a corresponding resistor 415a formed in the waveguide structure including the core layer 412 and the cladding layers 414a, 414b are coupled in series to the voltage Vs. The resistor 415a can be identical to the resistor 415b.

In the equivalent circuit diagram 450, without the illumination on the photoconductive material, the photoresistor 413b can be substantially larger than the resistor 415b. Thus, a first divided voltage on the photoresistor 413b can be close to Vs and a second divided voltage on the resistor 415b can be close to 0. Accordingly, there is no refractive index change, e.g., Δn=0. In contrast, in the equivalent circuit diagram 460, with the illumination on the photoconductive material, the photoresistor 413b can be changed to the photoresistor 413a which can be substantially smaller than the resistor 415a. Thus, a first divided voltage on the photoresistor 413a can be decreased to about 0, and a second divided voltage on the resistor 415a can be increased to about Vs. Accordingly, due to the DC Kerr effect and EFISH effect, there can be a change of refractive index and/or nonlinear susceptibility, e.g., Δn≠0, and/or χ⁽²⁾≠0.

Thus, when the patterned illumination 432 is on the photoconductive layer 418 and the voltage Vs is applied across the photonic planar waveguide 410, a 2D refractive index or nonlinear susceptibility variation in the core layer 412 can be obtained, and accordingly, an input optical signal 401 (e.g., 201 of FIG. 2 or 3) coupled into the core layer 412 can be manipulated to become an output optical signal 403 (e.g., 203 of FIG. 2 or 3).

FIG. 5 is a schematic diagram of another system 500 including another example programmable photonic planar waveguide 510.

Similar to the photonic planar waveguide 210 or 410, the photonic planar waveguide 510 includes a core layer 512 between a pair of cladding layers 514a, 514b. The photonic planar waveguide 510 can also include an upper planar electrode layer 516 and a lower planar electrode layer 518 respectively on an upper cladding layer 514a and a lower cladding layer 514b. In some cases, the core layer 512 can be the core layer 212 of FIG. 2 or 3 that includes a photoconductive material. In another cases, the core layer 512 can be the core layer 412 of FIG. 4A that includes a non-photoconductive material, and a separate photoconductive layer, e.g., the photoconductive layer 418 of FIG. 4A, can be in the photonic planar waveguide 510, e.g., between the upper planar electrode layer 516 and the upper cladding layer 514a.

However, different from the upper planar electrode layer 216a of FIG. 2 or 3, or 416a of FIG. 4A that is a planar layer, the upper planar electrode layer 516 includes an array of pixelated electrodes 517. The array of pixelated electrodes 517 can be physically fabricated (e.g., by photolithography), which may also define a resolution of the programmable photonic planar waveguide 510. Each pixelated electrode 517 in the pixelated electrode layer 516 can be configured to receive a respective voltage V (x,z), e.g., V₀₀, V₁₀, V₂₀, . . . , V₀ₘ, V₁ₘ, V₂ₘ, . . . , V₀ₙ, V₁ₙ, V₂ₙ. The lower planar electrode layer 518 can be commonly coupled to a ground. Respective voltages 520 to the pixelated electrodes 517 can be controlled to vary respective localized electric fields E_{DC}(x,z) across different regions of the core layer 512 to cause corresponding local variations in at least one of a refractive index or a nonlinear susceptibility of the core layer 512, which is different from using a patterned illumination as described in FIG. 2, 3, or 4A. Thus, an input optical signal 501 (e.g., 201 of FIG. 2 or 3) coupled into the core layer 412 can be manipulated to become an output optical signal 503 (e.g., 203 of FIG. 2 or 3).

The above implementations, as illustrated in FIGS. 1 to 5, have been discussed with respect to 2D photonic planar waveguides. The techniques implemented in the present disclosure can be also applied to 1D photonic waveguides.

In some implementations, a programmable photonic waveguide includes a 1D waveguide structure extending along a longitudinal direction and first and second planar electrode layers extending parallel to each other along the longitudinal direction. The 1D waveguide structure is between the first and second planar electrode layers. The 1D waveguide structure can include a waveguide core and a cladding layer surrounding the waveguide core. The 1D waveguide structure can also include a photoconductive layer that is made of a photoconductive material and extends along the longitudinal direction. The photoconductive layer can be included in the waveguide core or as part of the cladding layer, e.g., between the cladding layer and one of the first and second planar electrode layers.

In operation of the programmable photonic waveguide, a voltage is applied across the waveguide structure through the planar electrode layers, and a patterned illumination of light can be projected on a plurality of different corresponding areas of the photoconductive layer along the longitudinal direction to locally vary a conductivity of the photoconductive material in the photoconductive layer so as to cause corresponding local variations in at least one of a refractive index or a nonlinear susceptibility of the waveguide core along the longitudinal direction while the voltage is applied across the waveguide structure. An optical signal can be coupled into the waveguide core and propagate through the waveguide core with the corresponding local variations in the at least one of the refractive index or the nonlinear susceptibility along the longitudinal direction.

In the programmable photonic waveguide, light is confined to travel in 1D, which can have significant benefits such as achieving stronger nonlinear interactions or obtaining a specific desired optical spectral response.

The techniques implemented in the present disclosure can be also applied to 3D photonic device including photoconductive materials. For example, using two or more light beams to illuminate selective regions in a photoconductive material may generate a 3D refractive index or nonlinear susceptibility profile to thereby manipulate light in a 3D photonic device.

### Example Processes

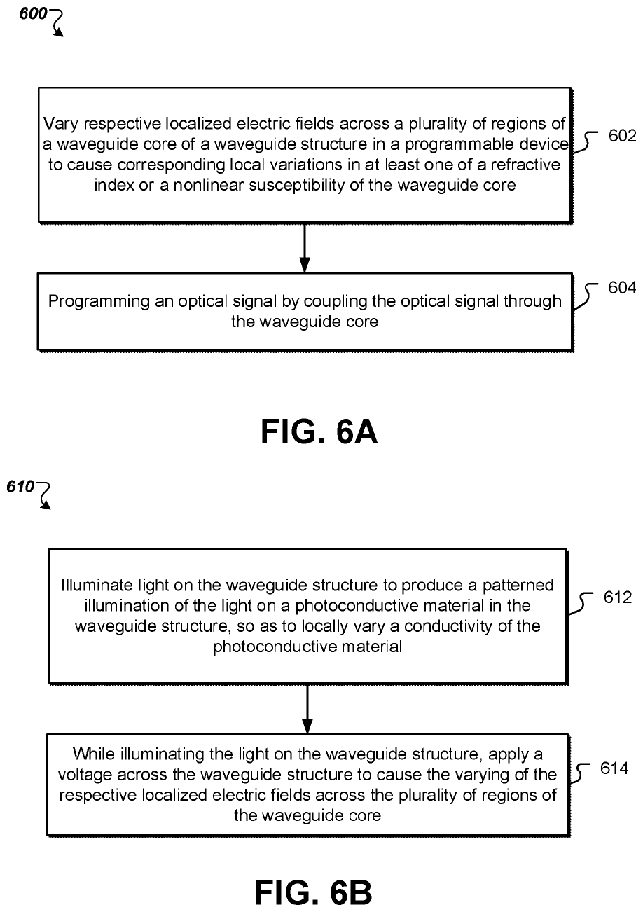

FIG. 6A is a flow diagram of an example process 600 of managing a programmable photonic waveguide. The programmable photonic waveguide can be the programmable photonic waveguide 100 of FIG. 1, 210 of FIG. 2 or 3, 410 of FIG. 4A, or 510 of FIG. 5. The process 600 can be performed by a system including the programmable photonic waveguide, e.g., the system 200 of FIG. 2, the system 300 of FIG. 3, the system 400 of FIG. 4A, or the system 500 of FIG. 5. The system can include a controller, e.g., the controller 260 of FIG. 2, configured to control an operation of the programmable photonic waveguide.

At 602, respective localized electric fields across a plurality of regions of a waveguide core of a waveguide structure in the programmable photonic waveguide are varied to cause corresponding local variations in at least one of a refractive index or a nonlinear susceptibility of the waveguide core. The waveguide core can be between a pair of cladding layers in the waveguide structure, such that light can be confined in the waveguide core and travel through the waveguide core.

At 604, an optical signal is programmed by coupling the optical signal through the waveguide core with the local variations in the at least one of the refractive index or the nonlinear susceptibility of the waveguide core.

In some implementations, the photonic waveguide can have a structure similar to the photonic waveguide 510 of FIG. 5. In the photonic waveguide, the waveguide structure is between first and second planar electrode layers (e.g., 516, 518 of FIG. 5). The first planar electrode layer (e.g., 516) can include a plurality of pixelated electrodes (e.g., 517 of FIG. 5) configured to receive respective voltages (e.g., 520 of FIG. 5). The second planar electrode layer can be commonly coupled to a ground. In operation, the respective localized electric fields across the plurality of regions of the waveguide core (e.g., the core layer 512 of FIG. 5) can be varied by changing the respective voltages coupled to the plurality of pixelated electrodes to vary the respective localized electric fields across the plurality of regions of the waveguide core. The plurality of pixelated electrodes correspond to the plurality of regions of the waveguide core.

In some implementations, the photonic waveguide can have a structure similar to the photonic waveguide 210 of FIG. 2 or 3, or 410 of FIG. 4A. The photonic waveguide includes a photoconductive material responsive to light illumination, which can be used to generate the localized electric fields in the waveguide core, e.g., the core layer 212 of FIG. 2 or 3, or the core layer 412 of FIG. 4A, as further discussed in FIG. 6B.

FIG. 6B is a flowchart of an example process 610 of generating the localized electric fields in the waveguide core. The process 610 can be implemented as step 602 of FIG. 6A.

At 612, light is illuminated on the photonic waveguide to produce a patterned illumination of the light on the photoconductive material to locally vary a conductivity of the photoconductive material.

In some implementations, as illustrated in FIG. 2, the light can be illuminated on the photonic waveguide by individually deflecting, e.g., by the optical deflecting device 230 of FIG. 2, respective illumination spots of the light onto a plurality of different corresponding areas of a top surface of the photonic waveguide to produce the patterned illumination of the light.

In some implementations, as illustrated in FIG. 3, the light can be illuminated on the photonic waveguide by sequentially scanning, e.g., by the optical scanning system 320 of FIG. 3, an illumination spot of the light across a plurality of different corresponding areas of a top surface of the photonic waveguide to generate the patterned illumination.

In some implementations, the light can be illuminated on the photonic waveguide by modulating a plurality of elements of a spatial light modulator (SLM) to diffract the light to generate the patterned illumination onto a plurality of different corresponding areas of a top surface of the photonic waveguide.

At 614, while illuminating the light on the photonic waveguide, a voltage is applied across the waveguide structure to cause the varying of the respective localized electric fields across the plurality of regions of the waveguide core. The patterned illumination of the light on the photoconductive material corresponds to the plurality of regions of the waveguide core.

Referring back to FIG. 6A, the process 600 can further include: generating a control signal based on at least one target optical signal. The at least one control signal can correspond to at least one of a two-dimensional (2D) refractive index profile or a 2D nonlinear susceptibility profile in the waveguide core.

In some implementations, the control signal is used to control at least one of: the illumination of the light on the photonic waveguide, the voltage applied across the waveguide structure, or the optical signal coupled through the waveguide core.

In some implementations, the process 600 can further include: receiving the programmed optical signal coupled out from the waveguide core, and adjusting the control signal based on a result of comparing the programmed optical signal to the at least one target optical signal.

In some implementations, the waveguide core includes the photoconductive material, e.g., as illustrated in FIG. 2 or 3. In some implementations, the photoconductive material is included in a photoconductive layer (e.g., 418 of FIG. 4A) that is arranged between an upper planar electrode layer (e.g., 416a of FIG. 4A) and an upper cladding layer (e.g., 414a of FIG. 4A). The light is illuminated on the photoconductive layer through the upper planar electrode layer.

In some examples, the photoconductive material includes at least one of: silicon-rich silicon nitride (SRN), silicon nitride, silicon carbide, amorphous silicon, crystalline silicon, liquid crystals, Barium titanate, or lithium niobate.

In some examples, the corresponding local variation of the refractive index of the waveguide core is in a range from 10⁻⁴ to more than 0.1. The corresponding local variation of a nonlinear second order susceptibility of the waveguide core can be in a range of 1 pm/V to more than 10³ pm/V.

### Example Applications

Programmable photonic devices implemented in the present disclosure, by their natures, can change their functionalities and thus can be applied in a variety of settings. A number of programmable photonic devices can be integrated in a chip to implement a number of different functions.

In some examples, a programmable photonic waveguide is used to instantiate general tunable optical components that are useful in a more general photonic context, e.g., for optical sensing or telecommunication applications. The optical components can include instantiating complex optical filters, optical demultiplexers/combiners, reconfigurable optical add-drop multiplexers, and/or complex optical cavities or devices,

In some examples, a programmable photonic waveguide can be used to perform machine learning classification, e.g., by inputting the machine learning data into an input port of the waveguide and an output predicted class can be read out from an output port of the waveguide after undergoing some complex wave-dynamics in an integrated photonic chip including the waveguide. A similar approach could also be used to solve other difficult computational problems that are industrially or scientifically relevant, e.g., combinatorial optimization problems or partial differential equations. In some examples, the programmable complex wave dynamics of light in the waveguide can be utilized to perform the computation of complex mathematical functions, e.g., fully programmable matrix multiplication.

The disclosed and other examples can be implemented as one or more computer program products, for example, one or more modules of computer program instructions encoded on a computer readable medium for execution by, or to control the operation of, data processing apparatus. The computer readable medium can be a machine-readable storage device, a machine-readable storage substrate, a memory device, or a combination of one or more them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A system may encompass all apparatus, devices, and machines for processing data, including by way of example a programmable processor, a computer, or multiple processors or computers. A system can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed for execution on one computer or on multiple computers that are located at one site or distributed across multiple sites and interconnected by a communications network.

The processes and logic flows described in this document can be performed by one or more programmable processors executing one or more computer programs to perform the functions described herein. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer can include a processor for performing instructions and one or more memory devices for storing instructions and data. Generally, a computer can also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data can include all forms of nonvolatile memory, media and memory devices, including by way of example semiconductor memory devices, e.g., EPROM, EEPROM, and flash memory devices; magnetic disks. The processor and the memory can be supplemented by, or incorporated in, special purpose logic circuitry.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

A number of implementations have been described. Nevertheless, it will be understood that various modifications may be made without departing from the spirit and scope of the techniques and devices described herein. For example, phase perturbation or variation methods discussed above may be implemented in diffractive structures to remove high frequency artifacts or medium frequency artifacts in interference patterns. Features shown in each of the implementations may be used independently or in combination with one another. Additional features and variations may be included in the implementations as well. Accordingly, other implementations are within the scope of the following claims.

What is claimed is:

1.-45. (canceled)

46. A programmable system, comprising:
a programmable device extending in a plane, the programmable device comprising:
a pair of planar electrode layers extending parallel to each other; and
a waveguide structure comprising a core layer and a pair of cladding layers on opposing sides of the core layer, the core layer being between the planar electrode layers, the waveguide structure comprising a photoconductive material;
a power source electrically connected to the planar electrode layers and configured to apply a voltage across the waveguide structure during operation of the programmable system;
a light source configured to produce an illumination at a wavelength to change a conductivity of the photoconductive material;
a spatial light controller arranged to receive the illumination from the light source and illuminate the photoconductive material with a patterned illumination to locally vary the conductivity of the photoconductive material while the voltage is applied across the waveguide structure; and
an optical signal source arranged to direct an optical signal to an edge of the waveguide structure to couple the optical signal into the core layer while the photoconductive material is illuminated with the patterned illumination and the voltage is applied across the waveguide structure.

47. The programmable system of claim 46, wherein the patterned illumination is configured to locally vary the conductivity of the photoconductive material to cause a corresponding local variation in at least one of a refractive index or a nonlinear susceptibility of the core layer during the operation of the programmable system.

48. The programmable system of claim 47, wherein the patterned illumination on the photoconductive material and the voltage applied across the waveguide structure generate local variations of electric fields across a plurality of regions of the core layer so as to cause corresponding local variations in the at least one of the refractive index or the nonlinear susceptibility of the core layer.

49. The programmable system of claim 47, wherein the corresponding local variation of the refractive index of the core layer is in a range from 10⁻⁴ to more than 0.1, and
wherein the corresponding local variation of a second order nonlinear susceptibility of the core layer is in a range from 1 pm/V to more than 10³ pm/V.

50. The programmable system of claim 46, wherein the core layer comprises the photoconductive material,
wherein at least one of the planar electrode layers is configured as at least part of the cladding layers, and
wherein the core layer is immediately adjacent to the pair of planar electrode layers that are between the pair of cladding layers.

51. The programmable system of claim 46, wherein the photoconductive material is arranged in a layer different from the core layer, and, wherein the layer including the photoconductive material is above the core layer and between an upper planar electrode layer of the planar electrode layers and an upper cladding layer of the cladding layers.

52. The programmable system of claim 46, wherein the spatial light controller comprises an optical deflecting device configured to individually deflect respective illumination spots of the illumination onto a plurality of different corresponding areas of a top surface of the programmable device to generate the patterned illumination.

53. The programmable system of claim 46, wherein the spatial light controller comprises an optical scanner configured to sequentially scan an illumination spot of the illumination from the light source across a plurality of different corresponding areas of a top surface of the programmable device to generate the patterned illumination.

54. The programmable system of claim 46, wherein the spatial light controller comprises a spatial light modulator (SLM) having a plurality of elements configured to be modulated to diffract the illumination from the light source to generate the patterned illumination onto a plurality of different corresponding areas of a top surface of the programmable device.

55. The programmable system of claim 46, further comprising a controller coupled to at least one of the power source, the light source, the spatial light controller, or the optical signal source,
wherein the controller is configured to:
generate at least one control signal based on at least one target optical signal, the at least one control signal corresponding to at least one of a two-dimensional (2D) refractive index profile or a 2D nonlinear susceptibility profile in the core layer, and
transmit the at least one control signal to the at least one of the power source, the light source, the spatial light controller, or the optical signal source.

56. The programmable system of claim 55, wherein the at least one control signal comprises at least one of:
a first control signal to the light source to generate a corresponding illumination,
a second control signal to the spatial light controller to control the corresponding illumination to generate a corresponding patterned illumination on the photoconductive material,
a third control signal to the power source to generate a corresponding voltage to be applied across the waveguide structure, or
a fourth control signal to the optical signal source to generate a corresponding input optical signal.

57. The programmable system of claim 46, further comprising an optical receiver configured to receive an output optical signal coupled out from the waveguide structure.

58. The programmable system of claim 46, wherein the photoconductive material comprises at least one of:
silicon-rich silicon nitride (SRN), silicon nitride, amorphous silicon, crystalline silicon, liquid crystals, Barium titanate, silicon carbide, aluminum nitride, or lithium niobate.

59. A programmable device, comprising:
a waveguide structure extending in a plane and having
a core layer, and
a pair of cladding layers on opposing sides of the core layer;
a pair of planar electrode layers extending parallel to each other, the core layer being between the planar electrode layer; and
a photoconductive layer comprising a photoconductive material,
wherein, in operation of the programmable device,
a voltage is applied across the waveguide structure through the planar electrode layers,
a patterned illumination of light is projected on individual areas of the photoconductive layer to locally vary a conductivity of the photoconductive material in the photoconductive layer so as to cause corresponding local variations in at least one of a refractive index or a nonlinear susceptibility of the core layer while the voltage is applied across the waveguide structure, and
an optical signal is coupled into the core layer and propagates through the core layer with the corresponding local variations in the at least one of the refractive index or the nonlinear susceptibility.

60. The programmable device of claim 59, wherein the core layer comprises the photoconductive layer, wherein at least one of the planar electrode layers is configured as at least part of the cladding layers, and wherein the core layer is immediately adjacent to the pair of planar electrode layers that are between the pair of cladding layers.

61. The programmable device of claim 59, wherein the photoconductive layer is different from the core layer, and
wherein the photoconductive layer is above the core layer and between an upper planar electrode layer of the planar electrode layers and an upper cladding layer of the cladding layers.

62. The programmable device of claim 59, wherein the patterned illumination on the photoconductive layer and the voltage applied across the waveguide structure generate local variations of electric fields across a plurality of different corresponding regions of the core layer, so as to cause the corresponding local variations in the at least one of the refractive index or the nonlinear susceptibility of the core layer.

63. A method of managing a programmable device, comprising:
illuminating light on the programmable device to produce a patterned illumination of the light on a photoconductive layer of the programmable device, so as to locally vary a conductivity of a photoconductive material in the photoconductive layer, wherein the programmable device extends in a plane and comprises a waveguide structure having a core layer and a pair of cladding layers on opposing sides of the core layer;
while illuminating the light on the programmable device, applying a voltage across the waveguide structure through a pair of planar electrode layers of the programmable device so as to cause corresponding local variations in at least one of a refractive index or a nonlinear susceptibility of the core layer; and
programming an optical signal by coupling the optical signal through the core layer with the corresponding local variations in the at least one of the refractive index or the nonlinear susceptibility of the core layer.

64. The method of claim 63, wherein illuminating the light on the programmable device comprises at least one of:
individually deflecting respective illumination spots of the light onto a plurality of different corresponding areas of a top surface of the programmable device to produce the patterned illumination of the light,
sequentially scanning an illumination spot of the light across a plurality of different corresponding areas of a top surface of the programmable device to generate the patterned illumination, or
modulating a plurality of elements of a spatial light modulator (SLM) to diffract the light to generate the patterned illumination onto a plurality of different corresponding areas of a top surface of the programmable device.

65. The method of claim 63, further comprising:
generating at least one control signal based on at least one target optical signal, the at least one control signal corresponding to at least one of a two-dimensional (2D) refractive index profile or a 2D nonlinear susceptibility profile in the core layer; and
using the control signal to control at least one of:
the illumination of the light on the programmable device,
the voltage applied across the waveguide structure, or
the optical signal coupled through the core layer.
receiving the programmed optical signal coupled out from the core layer; and
adjusting the control signal based on a result of comparing the programmed optical signal to the at least one target optical signal.
